(19) United States
(12) Patent Application Publication
(10) Pub. No.: US 2023/0390793 A1
(43) Pub. Date: Dec. 7, 2023

(54) NOZZLE, DEVELOPMENT DEVICE, AND METHOD FOR PROCESSING OBJECT BEING TREATED

(71) Applicant: SINTOKOGIO, LTD., Nagoya-shi, Aichi (JP)

(72) Inventors: Shinji KANDA, Nagoya-shi, Aichi (JP); Norihito SHIBUYA, Nagoya-shi, Aichi (JP)

(73) Assignee: SINTOKOGIO, LTD., Nagoya-shi, Aichi (JP)

(21) Appl. No.: 18/032,688

(22) PCT Filed: Dec. 14, 2020
(86) PCT No.: PCT/JP2020/046567

§ 371 Date: Apr. 19, 2023

(30) Foreign Application Priority Data
Nov. 30, 2020 (JP) 2020-198652

(51) Int. Cl. B05B 7/04; G03F 7/32

(52) U.S. Cl. CPC B05B 7/0416; G03F 7/32

(57) ABSTRACT

In one aspect, a nozzle for injecting a processing liquid is provided. The nozzle includes a cylindrical housing having a central axis, a liquid supply port to supply the processing liquid into the housing, a gas supply port to supply a compressed gas into the housing, and an injection port to inject the processing liquid together with the compressed gas, and the injection port has an annular shape extending around the central axis.

### TECHNICAL FIELD

The present disclosure relates to a nozzle, a developing device, and a processing method for a workpiece.

### BACKGROUND ART

Patent Literature 1 describes a developing device that supplies a developer to a resist film formed on a surface of a workpiece to develop the resist film. The developing device has a nozzle including an injection port having a horizontally long slit shape and injects a developer together with high-pressure air from the nozzle in a direction inclined to a lateral direction of the injection port to form a resist pattern on the workpiece.

### CITATION LIST

### Patent Literature

Patent Literature 1: Japanese Patent No. 5153332

### SUMMARY OF INVENTION

### Technical Problem

As described above, in the nozzle described in Patent Literature 1, the development of the resist film in the lateral direction is promoted by injecting the developer in the direction inclined to the lateral direction of the injection port. On the other hand, the progress of the development of the resist film in the longitudinal direction of the injection port is suppressed by supplying the developer from a direction substantially perpendicular to the resist film. Therefore, when the developing process is performed using the nozzle described in Patent Literature 1, the pattern dimension of the resist pattern may be different in the longitudinal direction and the lateral direction of the injection port. When processing a workpiece using such resist pattern, the processing precision of the workpiece may vary depending on the in-plane direction. Therefore, especially when high precision is required for processing of the workpiece, it may be difficult to process the workpiece with the required precision.

Accordingly, an object of the present disclosure is to improve the uniformity of processing of a workpiece.

### Solution to Problem

In one aspect, a nozzle for injecting a processing liquid is provided. The nozzle includes a cylindrical housing having a central axis. The housing includes a liquid supply port to supply the processing liquid into the housing, a gas supply port to supply a compressed gas into the housing, and an injection port to inject the processing liquid together with the compressed gas. The injection port has an annular shape extending around the central axis.

The nozzle according to the above aspect has an injection port having an annular shape, and the processing liquid from the liquid supply port and the compressed gas from the gas supply port are injected from the injection port. Since the processing liquid is uniformly injected from the injection port having an annular shape in the circumferential direction around the central axis, variations in the processing precision in the circumferential direction are suppressed. Therefore, it is possible to improve the uniformity of processing of the workpiece.

The nozzle of an embodiment may further include a rod member disposed between the liquid supply port and the injection port in an extending direction of the central axis, the rod member having an inclined surface in which a diameter increases toward the injection port, and a fluid passage may be formed between an inner peripheral surface of the housing and the inclined surface to guide the processing liquid supplied from the liquid supply port and the compressed gas supplied from the gas supply port to the injection port. The processing liquid and the compressed gas introduced into the fluid passage formed between the inner peripheral surface of the housing and the rod member are guided along the inclined surface of the rod member and injected from the injection port. Accordingly, since the processing liquid is injected in a direction inclined with respect to the central axis, the processing liquid can be uniformly supplied to the side wall of the opening of the workpiece. As a result, the processing precision of the workpiece can be improved.

The nozzle of one embodiment may be configured to atomize and inject the processing liquid from the injection port. Since the processing liquid is easily supplied to the inside of the opening of the workpiece by atomizing and injecting the processing liquid, it is possible to further improve the processing precision of the workpiece.

The nozzle of one embodiment may further include a liquid supply pipe to guide the processing liquid into the housing along the central axis, and a diffusion plate to diffuse the processing liquid flowing through the liquid supply pipe, the diffusion plate having a plurality of openings arranged along a circumferential direction about the central axis. In this embodiment, the processing liquid flowing through the liquid supply pipe collides with the diffusion plate to be diffused, and then is guided to the fluid passage together with the compressed air. By introducing the diffused processing liquid into the fluid passage, the uniformity of the processing liquid injected from the injection port may be improved.

In one embodiment, the processing liquid may be a developer to develop a resist film or an etching liquid to etch a workpiece. The workpiece can be processed with high uniformity by injecting the developer or the etching liquid from the nozzle described above onto the workpiece.

In one aspect, a developing device for developing a resist film formed on a workpiece is provided. The developing device includes a processing container, the nozzle disposed in the processing container, a conveying mechanism to move the workpiece relative to the nozzle in the processing container, a developer supply device to supply a developer as the processing liquid to the nozzle, and a compressed gas supply device to supply the compressed gas to the nozzle.

In the developing device according to the above-described aspect, the resist film can be developed with high uniformity. by injecting the developer together with the compressed gas from the nozzle to the workpiece.

In one embodiment, the developer supply device may supply the developer heated to 40° C. or more to the nozzle. By supplying the developer heated to 40° C. or more to the nozzle, the resist film can be effectively developed.

In one embodiment, the developing device may further include a recovery device to collect a gas containing the developer from the processing container and perform gas-liquid separation. By performing gas-liquid separation of the gas containing the developer by the recovery device, the developer can be recovered from the gas.

A processing method for a workpiece according to an aspect includes forming a photosensitive resist film on the workpiece, exposing the resist film, and injecting a developer with a compressed gas from a nozzle having an annular injection port to the exposed resist film to form a resist pattern.

In the processing method according to the above aspect, the resist pattern is formed by injecting the developer from the nozzle having the annular injection port. Since the developer is uniformly injected from the annular injection port in the circumferential direction of the injection port, the resist film can be developed with high uniformity. By using the resist pattern formed as described above, it is possible to improve the uniformity of processing on the workpiece.

In one embodiment, the atomized developer may be injected from the injection port. By injecting the atomized developer, the swelling of the resist film can be suppressed and the developer can be easily supplied to the inside of the opening of the resist film. Therefore, a pattern can be formed on the resist film with high precision.

In one embodiment, the developer may be injected in an injection pattern having an annular shape when viewed from a direction along a central axis of the injection port and having a diameter that increases with a distance from the injection port. By injecting the developer in the injection pattern, a pattern can be formed on the resist film with high uniformity and high precision.

In one embodiment, an injecting direction of the developer may be inclined at an angle of 10° or less with respect to the central axis. Since the developer can be uniformly supplied to the side wall of the opening of the resist film by injecting the developer in the direction inclined at an angle of 10° or less with respect to the central axis, a pattern can be formed on the resist film with high precision.

In one embodiment, the processing method may further include injecting abrasive to the workpiece through the resist pattern to remove a part of the workpiece. By processing the workpiece using the resist pattern formed by the above-described processing method, the workpiece can be processed with high uniformity.

In one embodiment, the processing method further include injecting an etching liquid from the nozzle to the workpiece through the resist pattern to remove a part of the workpiece. By injecting the etching liquid using the nozzle described above, the workpiece can be processed with high uniformity.

In one embodiment, the processing method may further include supplying a stripping liquid to the resist pattern to remove the resist pattern from the workpiece.

### Advantageous Effects of Invention

According to aspects and various embodiments of the present invention, it is possible to improve the uniformity of processing on a workpiece.

### BRIEF DESCRIPTION OF DRAWINGS

FIG. 1 is a diagram schematically illustrating a developing device according to an embodiment.

FIG. 2 is a perspective view of a nozzle according to an embodiment.

FIG. 3 is a cross-sectional view of a nozzle according to an embodiment.

FIG. 4 is a plan view of a diffusion plate.

FIG. 5 is a bottom view of an injection port.

FIG. 6 is a cross-sectional view of an injection flow of a developer taken along line VI-VI of FIG. 2.

FIG. 7 is a diagram illustrating a scanning direction of a nozzle with respect to a workpiece.

FIG. 8 is a view illustrating state in which a part of a resist film is removed by a developing process.

FIG. 9 is a flowchart illustrating a processing method for the workpiece according to an embodiment.

FIG. 10 is a diagram illustrating a step of forming the resist film.

FIG. 11 is a diagram illustrating a step of exposing the resist film.

FIG. 12 is a diagram illustrating a step of developing the resist film.

FIG. 13 is a diagram illustrating a step of blasting the workpiece.

FIG. 14 is a diagram illustrating a step of stripping the resist film.

FIG. 15(a) a is an SEM photograph showing the resist pattern formed according to Comparative Example 1, and FIG. 15(b) is an SEM photograph showing the resist pattern formed according to Example 1.

FIG. 16(a) a is an SEM photograph showing the resist pattern formed according to Comparative Example 2, and FIG. 16(b) is an SEM photograph showing the resist pattern formed according to Example 2.

### DESCRIPTION OF EMBODIMENTS

Hereinafter, embodiments of the present disclosure will be described with reference to the drawings. In the following description, the same or corresponding elements are denoted by the same reference numerals, and redundant description will not be repeated. The dimensional ratios in the drawings are not necessarily consistent with those in the description. In the following description, a photosensitive film to which a pattern is transferred by exposure is referred to as a resist film, and a film in which an opening having a shape corresponding to the pattern transferred to the resist film by developing the resist film is formed is referred to as a resist pattern.

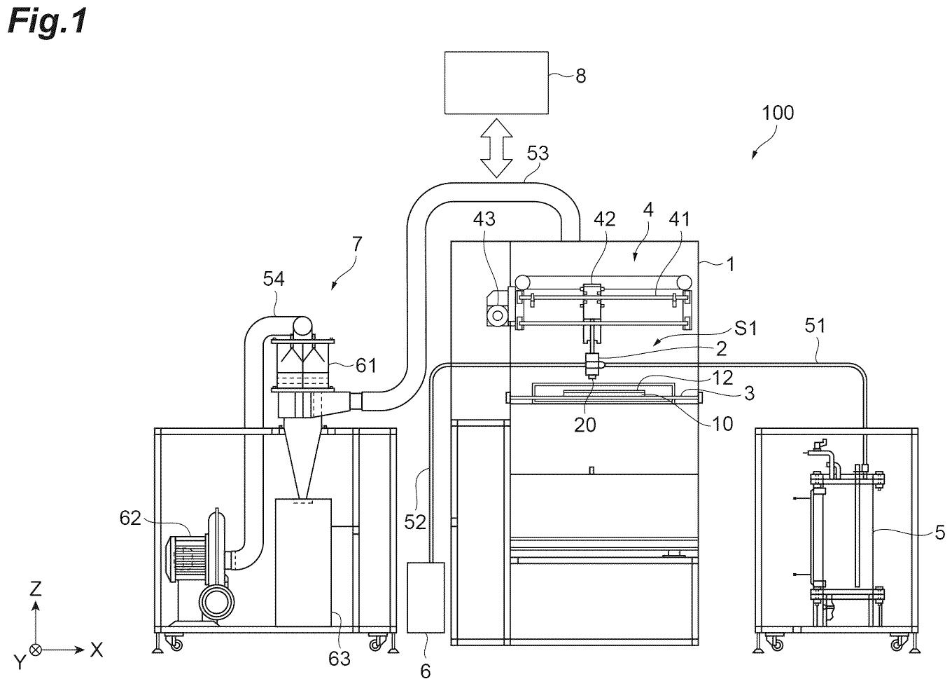

FIG. 1 is a diagram schematically illustrating a developing device 100 according to an embodiment. The developing device 100 shown in FIG. 1 develops a resist film on which a pattern has been exposed by photolithography, for example. In the following description, a movement direction of a nozzle 2 described later is referred to as an X direction, a conveying direction of a workpiece 10 described later is referred to as a Y direction, and a direction perpendicular to the X direction and the Y direction is referred to as a Z direction.

As shown in FIG. 1, the developing device 100 includes a processing container 1, a nozzle 2, a workpiece conveying mechanism 3, a nozzle conveying mechanism 4, a developer supply device 5, a compressed air supply device (compressed gas supply device) 6, and a recovery device 7.

The processing container 1 defines a developing chamber S1 therein. A workpiece 10 to be processed is disposed in the developing chamber S1. The workpiece 10 is a processed substrate such as a printed circuit board, a silicon substrate, a glass substrate, or a metal substrate, and may be an intermediate product obtained by performing predetermined processing on the processed substrate. A resist film 12 to which a predetermined pattern is transferred is formed on a surface of the workpiece 10. The resist film 12 is, for example, a dry film resist having photosensitivity.

The nozzle 2 is disposed in the developing chamber S1 such that an injection port 20 described later faces the workpiece 10. The nozzle 2 injects a developer 14 as a processing liquid onto the resist film 12 formed on the workpiece 10. The developing device 100 may include a plurality of nozzles 2.

The workpiece conveying mechanism 3 and the nozzle conveying mechanism 4 constitute a conveying device to move the workpiece 10 relative to the nozzle 2 in the developing chamber S1. The workpiece conveying mechanism 3 supports the workpiece 10 in the developing chamber S1. The workpiece conveying mechanism 3 is, for example, a belt conveyor device, and conveys the workpiece 10 placed thereon in the Y direction.

The nozzle conveying mechanism 4 holds the nozzle 2 in the developing chamber S1. The nozzle conveying mechanism 4 includes, for example, a rail 41 extending in the X direction, a holding member 42 that holds the nozzle 2, and a drive unit 43 that drives the holding member 42. The nozzle conveying mechanism 4 conveys the nozzle 2 in the X direction by moving the holding member 42 along the rail 41 by the driving force of the drive unit 43.

The developing device 100 may include one of the workpiece conveying mechanism 3 and the nozzle conveying mechanism 4 as a conveying device to move only one of the workpiece 10 and the nozzle 2 in the X direction and the Y direction, or may include both of the workpiece conveying mechanism 3 and the nozzle conveying mechanism 4 to move both of the workpiece 10 and the nozzle 2.

The developer supply device 5 stores the developer 14 for developing the resist film 12 in a high pressure and high temperature state. The developer 14 contains, for example, an aqueous solution of sodium carbonate. A pipe 51 is connected to the developer supply device 5, and the developer supply device 5 supplies the developer 14 to the nozzle 2 via the pipe 51. The developer supply device 5 may pressure-feed the developer 14 heated to 40° C. or higher to the nozzle 2.

The compressed air supply device 6 includes, for example, a compressor to supply compressed air (compressed gas) 15 to the nozzle 2 via a pipe 52. The pressure of the compressed air 15 supplied from the compressed air supply device 6 to the nozzle 2 may be slightly lower than the pressure of the developer 14 supplied from the developer supply device 5 to the nozzle 2. The injection amount of the developer 14 from the nozzle 2 is adjusted by adjusting the differential pressure between the pressure of the compressed air 15 supplied to the nozzle 2 and the pressure of the developer 14 supplied to the nozzle 2. The injection amount of the developer 14 increases as the differential pressure between the pressure of the compressed air 15 supplied to the nozzle 2 and the pressure of the developer 14 supplied to the nozzle 2 increases. For example, the differential pressure may be set to 0.01 MPa or more and 0.05 MPa or less. The compressed air supply device 6 may supply gas other than air to the nozzle 2.

The recovery device 7 collects gas containing the developer 14 from the developing chamber S1 to perform gas-liquid separation. As shown in FIG. 1, the recovery device 7 includes a gas-liquid separator 61. The gas-liquid separator 61 is, for example, a cyclone-type gas-liquid separator, and is connected to the developing chamber S1 via a pipe 53 and connected to a blower 62 via a pipe 54. When the resist film 12 is developed, the developer 14 and the compressed air 15 are injected from the nozzle 2 and the internal pressures of the developing chamber S1 is increased. Therefore, the developing chamber S1 is required to have a negative pressure. The blower 62 sucks gas in the gas-liquid separator 61 via the pipe 54. When the inside of the gas-liquid separator 61 becomes negative pressure by the blower 62, the gas containing the developer 14 in the developing chamber S1 is sucked into the gas-liquid separator 61 through the pipe 53. The gas-liquid separator 61 includes a filter, and collects the developer 14 contained in the sucked gas by the filter to recover the collected developer 14 in a recovery tank 63. The developer 14 recovered in the recovery tank 63 is reused for the developing process of the resist film 12.

Further, the developer 14 injected from the nozzle 2 is collected in a tank provided below the developing chamber S1. The developer 14 collected in the tank is discharged to the outside of the developing device 100 by a pump. The collected developer 14 may be returned to the developer supply device 5 and reused for the developing process of the resist film 12.

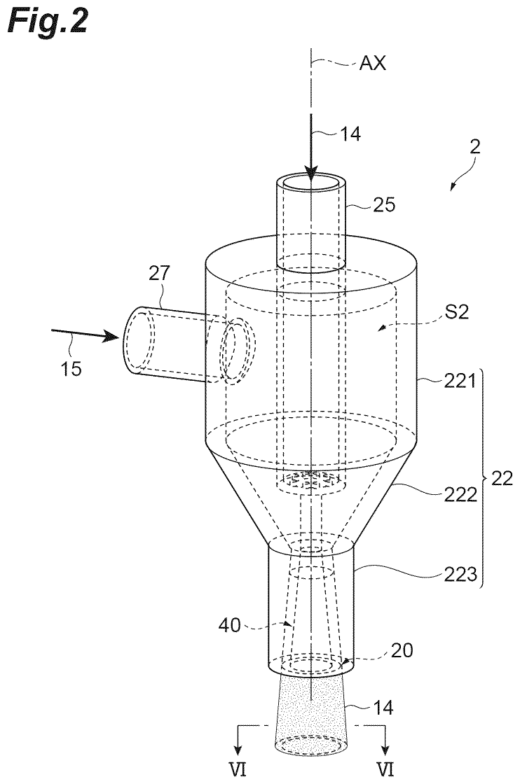

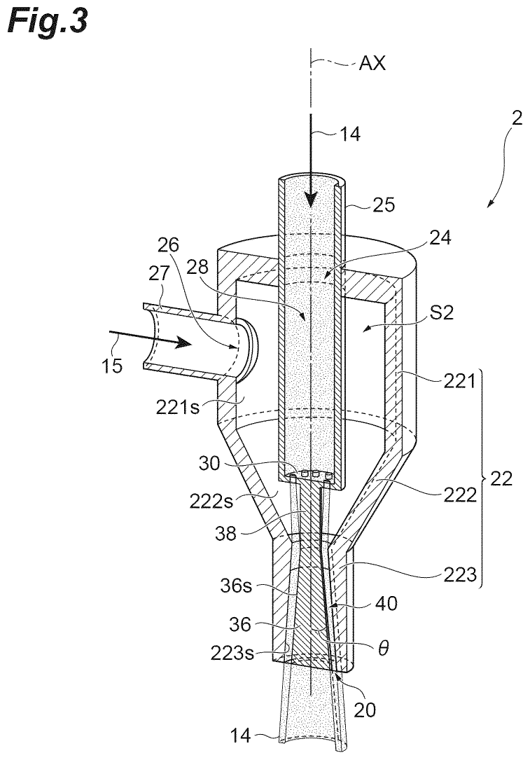

Referring to FIGS. 2 and 3, a nozzle according to an embodiment will be described in detail. FIG. 2 is a perspective view of the nozzle 2, and FIG. 3 is a cross-sectional view of the nozzle 2 taken along a central axis AX of the nozzle. As shown in FIGS. 2 and 3, the nozzle 2 has an injection port 20 having an annular shape, and injects the developer 14 and the compressed air 15 from the injection port 20 as a gas-liquid two phase flow. In the following description, a direction toward the injection port 20 may be referred to as a distal end side of the nozzle 2, and a direction opposite to the injection port 20 may be referred to as a proximal end side of the nozzle 2.

As shown in FIGS. 2 and 3, the nozzle 2 includes a cylindrical housing 22. The housing 22 has a cylindrical shape whose axial direction coincides with the central axis AX, and has a mixing chamber S2 therein. The housing 22 includes a base portion 221, a middle portion 222, and a tip portion 223. The base portion 221, the middle portion 222, and the tip portion 223 are arranged in this order from the proximal end side of the nozzle 2. The base portion 221, the middle portion 222, and the tip portion 223 may be integrally formed, or may be separately formed and connected to each other. An inner peripheral surface 221s of the base portion 221 has a substantially constant radius in a direction parallel to the central axis AX. An inner peripheral surface 222s of the middle portion 222 is gradually reduced in diameter toward the distal end side of the nozzle 2. An inner peripheral surface 223s of the tip portion 223 gradually increases in diameter toward the distal end side of the nozzle 2. The inner peripheral surface 221s of the base portion 221 and the inner peripheral surface 222s of the middle portion 222 define the mixing chamber S2. The inner peripheral surface 223s of the tip portion 223 defines a fluid passage 40 to be described later.

A liquid supply port 24 for supplying the developer 14 into the housing 22 and a gas supply port 26 for supplying the compressed air 15 into the housing 22 are formed in the housing 22. The liquid supply port 24 is formed on the central axis AX of the housing 22, and the liquid supply pipe 25 is inserted into the liquid supply port 24. The liquid supply pipe 25 provides an introduction path 28 for introducing the developer 14 into the mixing chamber S2 along the central axis AX. A proximal end of the liquid supply pipe 25 is connected to the pipe 51. An distal end of the liquid supply pipe 25 is disposed in the mixing chamber S2. The developer 14 supplied from the developer supply device 5 is guided to the mixing chamber S2 through the pipe 51 and the liquid supply pipe 25.

In one embodiment, a diffusion plate 30 to diffuse the developer 14 flowing through the liquid supply pipe 25 may be provided at the distal end of the liquid supply pipe 25. The diffusion plate 30 has a substantially disk shape and is disposed on the central axis AX.

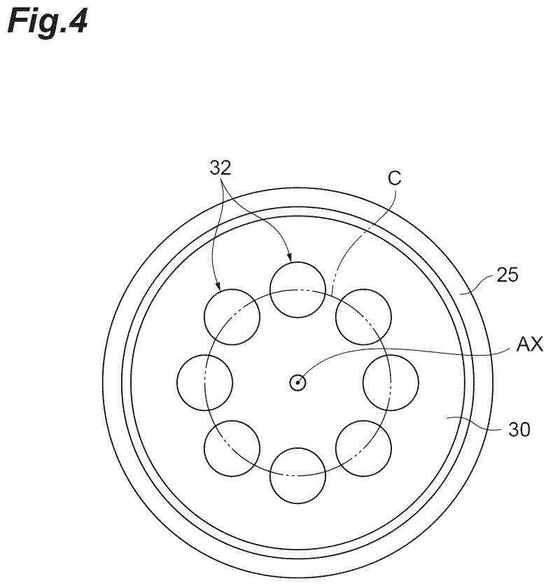

FIG. 4 is a plan view of the diffusion plate 30. As shown in FIG. 4, a plurality of openings 32 through which the developer 14 can pass are formed in the diffusion plate 30. The plurality of openings 32 are arranged at equal intervals along a virtual circle C centered on the central axis AX. The diffusion plate 30 diffuses the developer 14 flowing in the introduction path 28 in the central axis AX direction, and injects the developer 14 from the plurality of openings 32.

The gas supply port 26 is formed in the base portion 221 of the housing 22. A gas supply pipe 27 is connected to the gas supply port 26. The gas supply pipe 27 is connected to the compressed air supply device 6 via the pipe 52. The compressed air 15 supplied from the compressed air supply device 6 is guided to the mixing chamber S2 via the pipe 52 and the gas supply pipe 27, and mixed with the developer 14 in the mixing chamber S2.

The nozzle 2 further includes a rod member 36 and a protruding portion 38. The rod member 36 and the protruding portion 38 are disposed between the liquid supply port 24 and the injection port 20 in a direction parallel to the central axis AX. The protruding portion 38 has a substantially cylindrical shape and is connected to the lower surface of the diffusion plate 30. The upper surface of the rod member 36 has substantially the same diameter as the protruding portion 38, and is fixed to the protruding portion 38. The lower surface of the rod member 36 has a diameter larger than that of the upper surface of the rod member 36. That is, the rod member 36 has a truncated conical shape whose radius increases toward the distal end side of the nozzle 2, and has an inclined surface 36s whose radius increases toward the injection port 20.

As shown in FIG. 3, the inclined surface 36s is inclined at an angle θ with respect to the central axis AX. The angle θ is arbitrarily set in accordance with a pattern dimension or the like to be formed in the resist pattern. The injection angle of the developer 14 injected from the injection port 20 is determined according to the angle θ. For example, the angle θ is set to be greater than 0° and equal to or less than 10°.

The inclined surface 36s of the rod member 36 is disposed to face the inner peripheral surface 223s of the tip portion 223 with a gap therebetween. In other words, the inner peripheral surface 223s of the tip portion 223 is disposed to surround the inclined surface 36s of the rod member 36. A fluid passage 40 to guide the developer 14 supplied from the liquid supply port 24 and the compressed air 15 supplied from the gas supply port 26 from the mixing chamber S2 to the injection port 20 is formed between the inner peripheral surface 223s and the inclined surface 36s.

The fluid passage 40 extends along the inclined surface 36s of the rod member 36 and has a substantially constant width (i.e., the distance between the inner peripheral surface 223s and the inclined surface 36s) in the extending direction of the fluid passage 40. The fluid passage 40 has an annular shape when viewed from a cross-section perpendicular to the central axis AX, and the diameter of the fluid passage 40 increases toward the injection port 20. The fluid passage 40 guides the developer 14 and the compressed air 15 mixed in the mixing chamber S2 to the injection port 20.

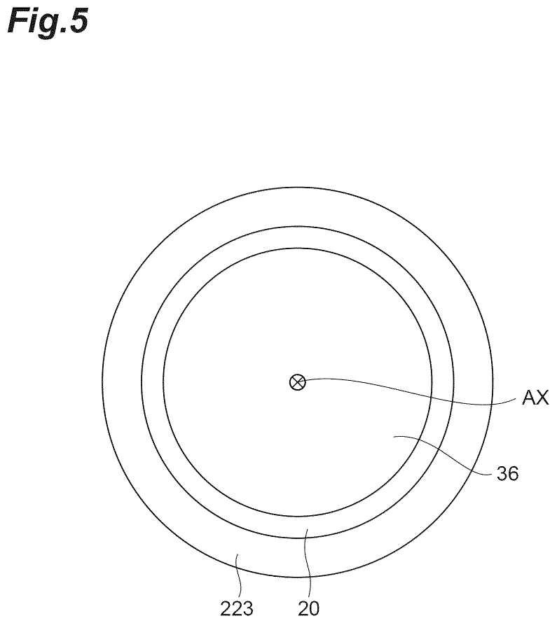

An outlet of the fluid passage 40 constitutes the injection port 20 to inject the developer 14 and the compressed air 15. FIG. 5 is a bottom view of the nozzle 2. As shown in FIG. 5, the injection port 20 of the nozzle 2 is formed between the lower surface of the rod member 36 and the lower surface of the inner peripheral surface 223s of the tip portion 223, and has an annular shape centered on the central axis AX. When the developer 14 is injected from the injection port 20, the developer 14 is atomized by the shearing force of the compressed air 15 and is injected.

The flows of the developer 14 and the compressed air 15 in the nozzle 2 will be described with reference to FIG. 3. The developer 14 supplied from the developer supply device 5 is guided to the liquid supply pipe 25 through the pipe 51 and flows in the introduction path 28 along the extending direction of the central axis AX. The developer 14 that has reached an end of the introduction path 28 collides with the diffusion plate 30 and is diffused in the introduction path 28. The developer 14 diffused in the introduction path 28 randomly passes through any one of the plurality of openings 32 and is injected to the mixing chamber S2. As a result, a uniform amount of the developer 14 is discharged from the plurality of openings 32.

On the other hand, the compressed air 15 supplied from the compressed air supply device 6 is introduced into the mixing chamber S2 through the pipe 52 and the gas supply port 26. The compressed air 15 introduced into the mixing chamber S2 is mixed with the developer 14 passing through the plurality of openings 32 and guided to the fluid passage 40 together with the developer 14 along the inner peripheral surface 222s of the middle portion 222. Then, the developer 14 and the compressed air 15 are introduced into the inlet of the fluid passage 40 and flow through the fluid passage 40 toward the injection port 20. At this time, a flowing direction of the developer 14 and the compressed air 15 is adjusted to a direction along the inclined surface 36s of the rod member 36. The developer 14 having flowed through the fluid passage 40 is injected from the annular injection port 20 together with the compressed air 15. At this time, the developer 14 is sheared by the compressed air 15 and injected from the injection port 20 in a mist form.

The injection direction of the developer 14 from the injection port 20 coincides with the inclination direction of the inclined surface 36s of the rod member 36. That is, the injection angle of the developer 14 from the injection port 20 with respect to the central axis AX coincides with the angle θ of the inclined surface 36s. That is, the developer 14 is injected from the injection port 20 at an angle θ of 10° or less with respect to the central axis AX. The developer 14 is injected from the injection port 20 at an angle larger than 0° with respect to the central axis AX.

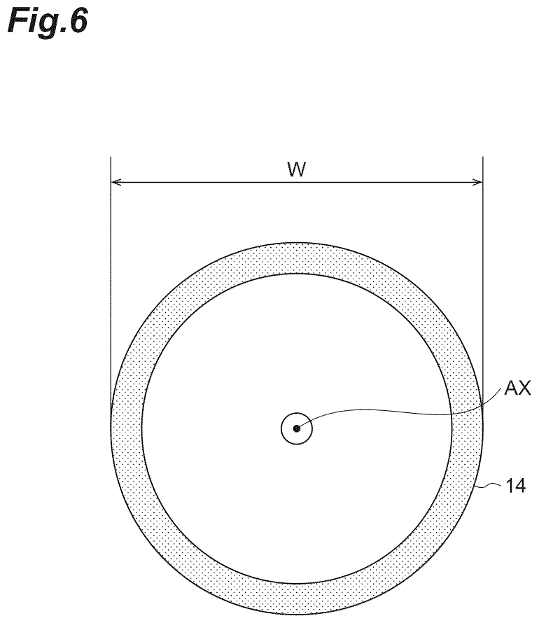

FIG. 6 is a cross-sectional view of the injection flow of the developer 14 taken along line VI-VI of FIG. 2. Since the injection port 20 has an annular shape, as shown in FIG. 6, the flow of the developer 14 injected from the injection port 20 has an annular pattern when viewed from a cross-section perpendicular to the central axis AX. Further, since the developer 14 is injected from the injection port 20 at the angle θ with respect to the central axis AX, the injection width W of the developer 14 increases as the distance from the injection port 20 increases. That is, the developer 14 is injected from the injection port 20 having an annular shape in an injection pattern of a hollow cone shape. By injecting the developer 14 in such injection pattern, the resist film 12 can be developed with high uniformity and high precision.

Reference is again made to FIG. 1. As shown in FIG. 1, the developing device 100 further includes a control device 8. The control device 8 is a computer including a processor, a storage unit, an input device, a display device, and the like, and controls each unit of the developing device 100. In the control device 8, an operator can perform an input operation or the like of a command to manage the developing device 100 by using the input device, and an operation state of the developing device 100 can be visualized and displayed by the display device. The storage unit of the developing device 100 stores a control program for controlling various processes executed by the developing device 100 by the processor, and a program for causing each component of the developing device 100 to execute a process according to a process condition.

The control device 8 is communicably connected to the workpiece conveying mechanism 3, the nozzle conveying mechanism 4, the developer supply device 5, the compressed air supply device 6, and the recovery device 7. For example, the control device 8 sends control signals to the developer supply device 5 and the compressed air supply device 6 to control the flow rates of the developer 14 and the compressed air 15 supplied to the nozzle 2. Further, the control device 8 sends control signals to the recovery device 7 to control the operations of the gas-liquid separator 61 and the blower 62. Further, the control device 8 sends control signals to the workpiece conveying mechanism 3 and the nozzle conveying mechanism 4 to control the conveying speed of the workpiece 10 in the Y direction and the moving speed of the nozzle 2 in the X direction.

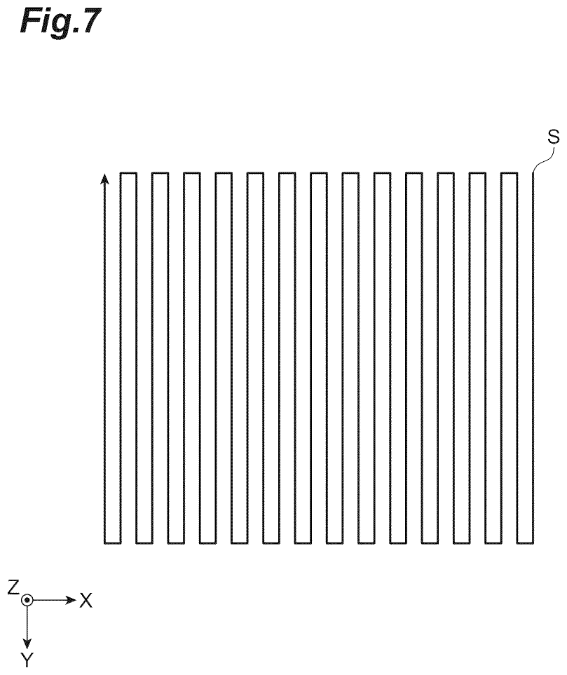

FIG. 7 is a diagram schematically showing the relative movement direction of the nozzle 2 relative to the workpiece 10. In a state where the developer 14 and the compressed air 15 are supplied to the nozzle 2, the control device 8 controls the workpiece conveying mechanism 3 to move the workpiece 10 from the start position S to one side in the Y direction at a constant speed, and then controls the nozzle conveying mechanism 4 to move the nozzle 2 to one side in the X direction at a constant speed. Next, the control device 8 controls the workpiece conveying mechanism 3 to move the workpiece 10 to the other side in the Y direction at a constant speed, and then controls the nozzle conveying mechanism 4 to move the nozzle 2 to the one side in the X direction at a constant speed. As described above, the control device 8 repeatedly controls the workpiece conveying mechanism 3 and the nozzle conveying mechanism 4 to two dimensionally scan the workpiece 10 with the nozzle 2, thereby uniformly injecting the developer 14 onto the entire surface of the resist film 12 formed on the workpiece 10.

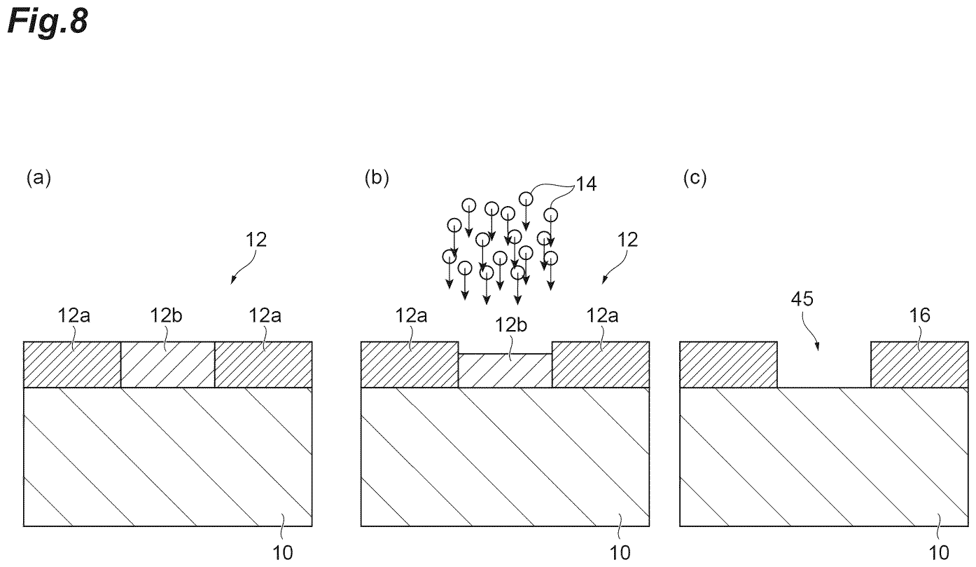

As described above, the developer 14 is injected onto the resist film 12 formed on the workpiece 10 to develop the resist film 12. FIG. 8(a) is a cross-sectional view showing the resist film 12 including an exposed region 12a that has been exposed and an unexposed region 12b that has not been exposed. As shown in FIG. 8(b), when the developer 14 is injected from the injection port 20 of the nozzle 2 to the resist film 12, the unexposed region 12b of the resist film 12 is dissolved and selectively removed. As shown in FIG. 8(c), when the exposure region 12a of the resist film 12 is completely removed, a resist pattern 16 in which an opening 45 corresponding to an exposed pattern is formed is obtained.

As described above, the developing device 100 injects the developer 14 from the annular injection port 20 in an injection pattern having a hollow cone shape. Since the developer 14 injected from the nozzle 2 is uniformly injected in the circumferential direction of the injection port 20, the resist pattern 16 can be formed with high uniformity. In addition, by injecting the developer 14 from the annular injection port 20, the developer 14 can be supplied in a wider range compared to the case where the developer is injected from a circular injection port, for example, and thus the developing process of the resist film 12 can be accelerated.

In addition, since the developer 14 is injected from the nozzle 2 in a direction inclined at the angle θ with respect to the central axis AX, the developer 14 can be uniformly supplied to the side wall of the exposure region 12a of the resist film 12. As a result, the verticality of the opening 45 of the resist pattern 16 can be enhanced, and the pattern can be formed with high precision. For example, since the energy ray L irradiated to the resist film 12 at the time of exposure attenuates toward the lower portion of the resist film 12, the side wall of the opening of the resist film 12 is likely to have a reverse tapered shape in which the width is narrowed toward the lower portion at the time of development. Therefore, when the developer 14 is injected in a direction parallel to the central axis AX, the developer 14 may not directly hit the side wall of the resist film 12, and a development residue may be generated at the lower portion of the resist film 12. In contrast, by injecting the developer 14 from the nozzle 2 in a direction inclined at an angle θ with respect to the central axis AX, the developer 14 can be brought into direct contact with the side wall of the lower portion of the resist film 12, so that the resist pattern 16 having a fine and highly uniform pattern can be formed even when the film thickness of the resist film 12 is large.

Further, in the conventional developing device, the resist film 12 may swell due to permeation of the developer 14 during development of the resist film 12. Swelling of the resist film 12 causes a reduction in the width of the opening 45 formed in the resist pattern 16. In contrast, in the developing device 100 described above, since the atomized developer 14 is injected at high speed from the injection port 20 of the nozzle 2, the permeation of the developer 14 into the resist film 12 is suppressed, and the swelling of the resist film 12 is suppressed. Further, since the atomized developer 14 enters deep into the unexposed region 12b of the resist film 12, the verticality of the opening 45 can be improved. Therefore, the precision of the pattern formed in the resist pattern 16 can be improved.

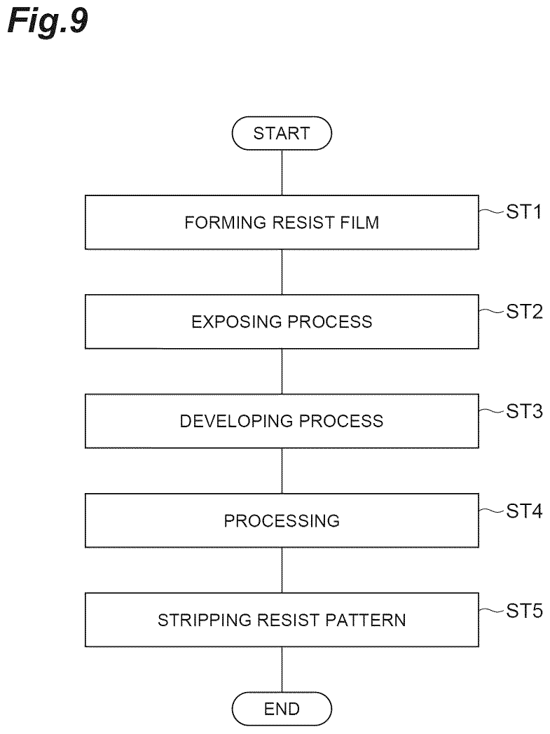

Next, a processing method for the workpiece according to one embodiment will be described. FIG. 9 is a flowchart illustrating a processing method for the workpiece according to one embodiment. The method is performed using a substrate processing system that includes the developing device 100. Hereinafter, a method of removing a portion of the workpiece 10 by processing the workpiece 10 using the resist pattern 16 having an opening will be described.

In this method, first, the resist film 12 is formed on the workpiece 10 (step ST1: forming the resist film). The resist film 12 formed on the workpiece 10 is a photoresist, and for example, a liquid resist or a dry film resist is used. When the resist film 12 is formed using a liquid resist, the liquid resist is uniformly applied onto the workpiece 10 using a coater (for example, a spin coater, a roll coater, a die coater, a bar coater, or the like) or by screen printing. Thereafter, the applied liquid resist is dried to form the resist film 12 on the workpiece 10.

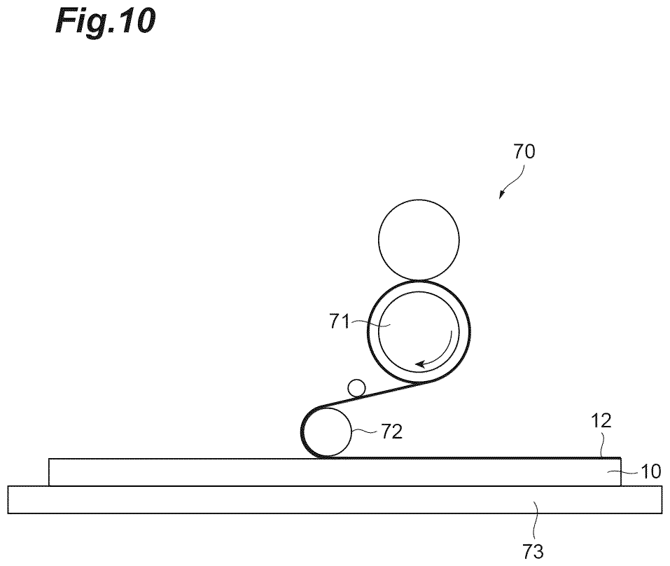

On the other hand, when the resist film 12 is formed using a dry film resist, a laminating device is used. FIG. 10 illustrates an exemplary laminating device 70 used to form the resist film 12. The laminating device 70 includes a supply roller 71 to hold a photosensitive dry film resist, a pressing roller 72 to wind up the dry film resist and press the dry film resist against the workpiece 10, and a table 73 to support the workpiece 10. The pressing roller 72 applies pressure to the dry film resist wound from the supply roller 71 while peeling off a protective film, thereby attaching the dry film resist onto the workpiece 10. The pressing roller 72 may include, for example, a heating element, and press the dry film resist against the upper surface of the workpiece 10 while heating the dry film resist. Thus, the resist film 12 is formed on the upper surface of the workpiece 10. A heating element may also be provided inside the table 73, and the dry film resist may be attached to the workpiece 10 by heating the dry film resist using one or both of the pressing roller 72 and the table 73.

The laminating condition of the dry film resist is appropriately set according to the processing condition of the workpiece 10. For example, when an alumina substrate having a diameter of 300 mm and a thickness of 10 mm is used as the workpiece 10 and the resist pattern 16 having a dot shape having a diameter of 500 μm is formed on the workpiece 10, a dry film resist is formed on the workpiece 10 under the following laminating condition as an example.

(Laminating Condition)
Set temperature of the table: 70° C.
Conveyance speed of the table: 500 mm/min

The resist material contained in the dry film resist or the resist liquid may be a positive resist material or a negative resist material. The positive resist material is a resist material in which the exposure region 12a of the resist film 12 is dissolved and the unexposed region 12b remains. The negative resist material is a resist material in which the unexposed region 12b of the resist film 12 is dissolved and the exposure region 12a remains.

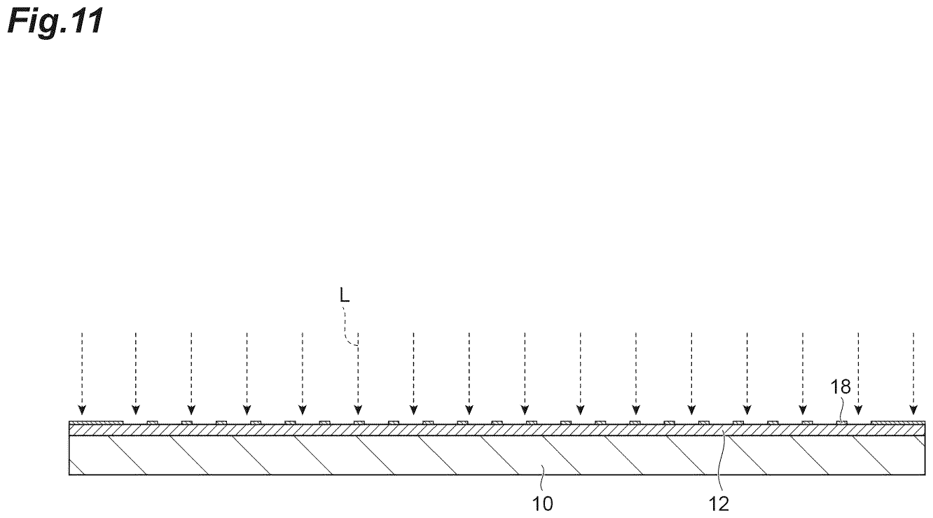

Next, the resist film 12 formed on the workpiece 10 is exposed by the exposing device (step ST2: exposing process). As shown in FIG. 11, this step is performed by irradiating the resist film 12 with energy rays L (for example, visible light or ultraviolet light) from a light source of the exposing device via a pattern mask 18 having a predetermined pattern, for example. As the pattern mask 18, for example, a negative mask having a configuration in which a black film is formed on a transparent plate (for example, glass, film, or the like) and having a region through which the energy rays L pass and a region through which the energy rays L do not pass is used. As a light source for irradiating the energy rays L, for example, an LED lamp, a mercury lamp, a metal halide lamp, an excimer lamp, a xenon lamp, or the like is used. In one example, the resist film 12 is irradiated with ultraviolet light from an ultra-high pressure mercury lamp. By this exposing process, the pattern of the pattern mask 18 is transferred to the resist film 12.

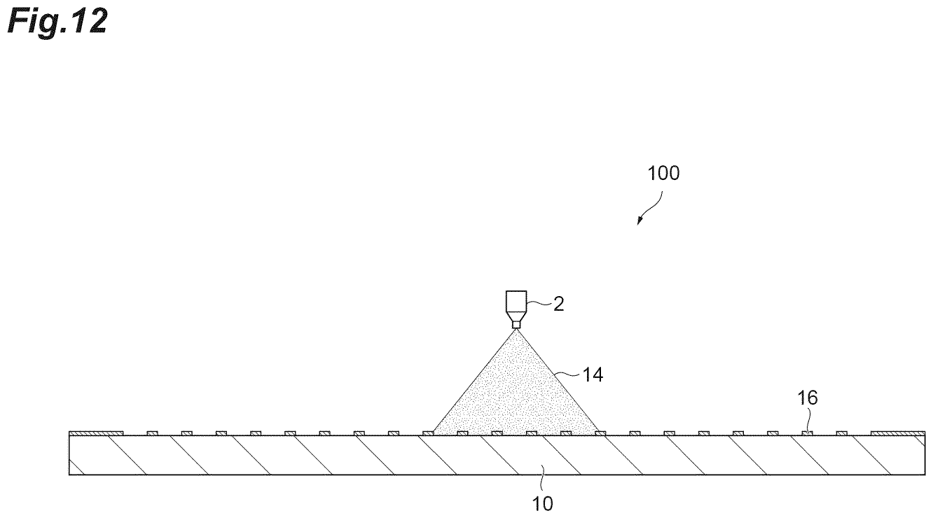

Next, the pattern transferred to the resist film 12 is developed (step ST3: developing process). In this step, the resist film 12 is developed by spraying the developer 14 onto the resist film 12. As a conventional developing device, a shower-type developing device is generally known in which a developer pressurized by a pump is injected using a developer injection nozzle. In the shower type developing device, it is difficult to supply the developer 14 into the fine pattern and to develop the fine pattern with high precision. In contrast, in the method of processing the workpiece according to the embodiment, the resist film 12 is developed using the developing device 100 shown in FIG. 1. For example, the developing device 100 injects the developer 14 together with the compressed air 15 from the nozzle 2 having the annular injection port 20 onto the resist film 12 while scanning the nozzle 2 in the X direction and the Y direction relative to the workpiece 10. For example, in the step ST3, as shown in FIG. 1, while the nozzle 2 is moved at high speed in the left-right direction (the X direction) using the nozzle conveying mechanism 4, the workpiece 10 is moved in the front-rear direction (the Y direction) using the workpiece conveying mechanism 3. At this time, the atomized developer 14 is injected from the injection port 20 to the resist film 12 in an injection pattern having a hollow cone shape. By injecting the developer 14 to the resist film 12, an exposed region or an unexposed region of the resist film 12 is selectively removed. Thereafter, the developed resist film 12 is washed with water and air-blown to form a resist pattern 16 having a fine and uniform pattern on the workpiece 10 as shown in FIG. 12.

A developing condition of the resist film 12 by the exposing device is appropriately set according to the shape and dimensions of the pattern formed in the resist pattern 16. For example, when the resist pattern 16 having a dot shape having a diameter of 500 pm is formed, the resist film 12 is developed under the following developing condition.

(Developing Condition)
Developer: alkaline aqueous solution
Temperature of the developer: 40° C.
Movement range of the nozzle: 500 mm
Movement speed of the nozzle: 10 m/min
Movement speed of the workpiece: 100 mm/min

In one embodiment, in order to cure the resist film 12, the workpiece 10 may be transported to a heating furnace to be subjected to heat treatment (pre-baking) before the developing process. After the developing process, the workpiece 10 may be subjected to a cleaning process and a reheating process (post-baking).

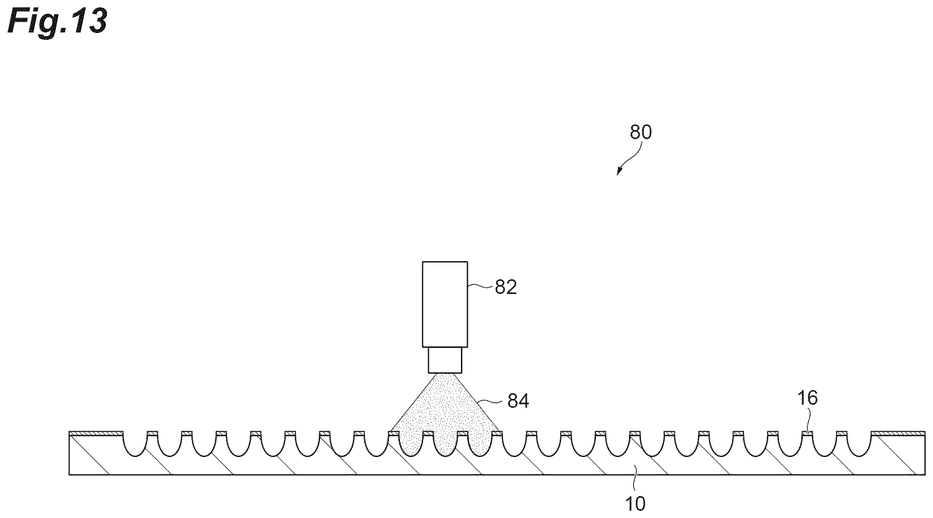

Next, the workpiece 10 is processed (step ST4: processing). For example, this processing is an etching process. For example, the etching process is a blasting process. For example, the blasting process is performed by a blasting device 80. As shown in FIG. 13, the blasting device 80 blows compressed air and abrasive 84 to the workpiece 10 via the resist pattern 16 while scanning the blast nozzle 82 in the left-right direction and the front-rear direction to cut and remove a portion of the surface of the workpiece 10 exposed from the opening of the resist pattern 16. As a result, the pattern of the resist pattern 16 is transferred to the workpiece 10.

The blasting condition of the workpiece 10 is appropriately set according to the pattern to be formed in the workpiece 10. For example, when a hole having a depth of 50 μm is formed in the workpiece 10 using the above-described resist pattern 16, the workpiece 10 is processed under the following blasting condition.

(Blasting Condition)
Moving speed of the blast nozzle: 10 m/min
Injection internal pressure of the blast nozzle: 0.25 MPa

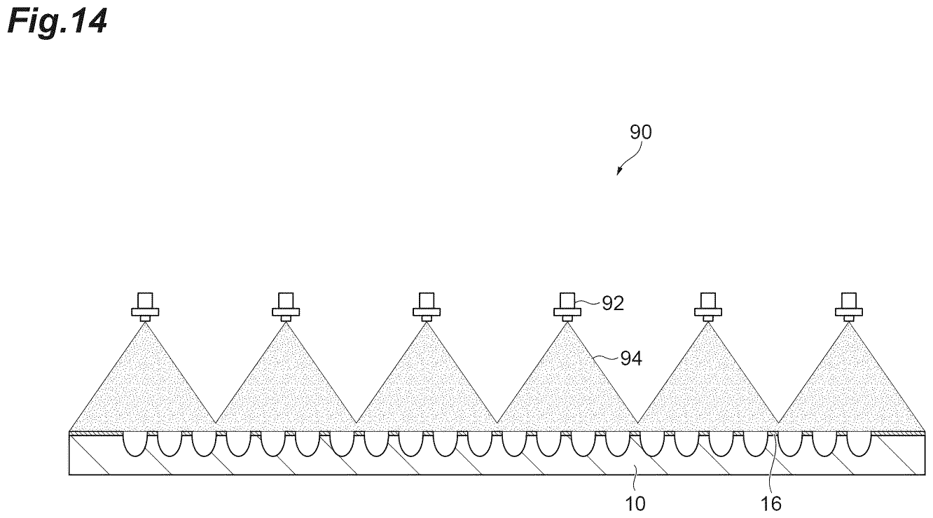

Next, the resist pattern 16 is stripped from the workpiece 10 by the stripping device 90 (step ST5). For example, as shown in FIG. 14, the stripping device 90 removes the resist pattern 16 from the surface of the workpiece 10 by spraying the stripping liquid 94 from the spray nozzle 92 onto the surface of the workpiece 10. The workpiece 10 on which a fine pattern is formed is manufactured by the above-described series of processes.

Although the nozzle 2, the developing device 100 and the processing method for the workpiece 10 according to various embodiments have been described above, the present disclosure is not limited to the above-described embodiments, and various modifications may be made without departing from the scope of the present invention.

For example, in the above-described embodiment, the developer 14 is injected from the nozzle 2 together with the compressed air 15, but in one embodiment, the etching liquid may be injected from the nozzle 2. In this case, the etching device including the nozzle 2 supplies the etching liquid as the processing liquid to the liquid supply pipe 25 of the nozzle 2 and supplies compressed air to the gas supply pipe 27. Accordingly, the etching liquid and the compressed air are mixed in the mixing chamber S2, and the atomized etching liquid is injected from the injection port 20 having an annular shape in an injection pattern having a hollow cone shape. Since the etching liquid is uniformly supplied to the side wall of the opening of the workpiece 10 by injecting the atomized etching liquid to the workpiece 10 through the resist pattern 16 in the injection pattern having a hollow cone shape, the workpiece 10 can be processed with high precision.

In addition, in the step ST4 of the processing method for the workpiece 10 illustrated in FIG. 9, a portion of the workpiece 10 is removed by blasting the workpiece 10 through the resist pattern 16, but in one embodiment, a portion of the workpiece 10 may be removed by wet etching (chemical etching). Wet etching is a method of partially removing the workpiece 10 by chemically corroding the surface of the workpiece 10 using an etching liquid (chemical liquid). In one embodiment, the workpiece 10 may be immersed in the etching liquid or the etching liquid may be sprayed onto the workpiece 10 through the resist pattern 16 to remove a portion of the workpiece 10. In a case where the etching liquid is sprayed onto the workpiece 10, the etching liquid may be sprayed onto the workpiece 10 from the nozzle 2 in the injection pattern having a hollow cone shape. The workpiece 10 can be processed with high uniformity and precision by injecting the etching liquid to the workpiece 10 from the nozzle 2 having an annular shape.

In another embodiment, the workpiece 10 may be plated using the resist pattern 16 that has been developed in the step ST4. A metal mask having a shape corresponding to a shape of the pattern formed in the resist pattern 16 can be formed on the workpiece 10 by, for example, forming a plating layer through the resist pattern 16 formed on the workpiece 10.

For example, when a dry film resist is attached on a stainless steel substrate having a size of 300 mm by 300 mm to form a resist pattern 16 having a dot shape and a metal mask is formed on the workpiece 10 using the resist pattern 16, forming the resist film 12, exposing process, and developing process are performed according to the following laminating condition, exposing condition, and developing condition, for example.

(Laminating Condition)
Set temperature of the table: 70° C.
Conveyance speed of the table: 500 mm/min

(Exposing Condition)
Energy ray: ultraviolet ray

(Developing Condition)
Developer: alkaline aqueous solution
Temperature of the developer: 60° C.
Movement range of the nozzle: 400 mm
Movement speed of the nozzle: 10 m/min
Movement speed of the workpiece: 30 mm/min

In this embodiment, a nickel plating layer is formed by electroplating on the workpiece 10 having the resist pattern 16 formed under the above-described conditions. Then, a stripping liquid 94 is used to strip the resist pattern 16 to form a metal mask.

Hereinafter, effects of the nozzle 2 and the developing device 100 will be described with reference to examples and comparative examples, but the present invention is not limited to the following examples.

In Example 1 and Comparative Example 1, a photosensitive dry film resist was formed on the workpiece 10, and the dry film resist was exposed and developed using a photolithography technique to form a resist pattern 16 for wet etching covering a part of the workpiece 10. The design dimensions of the resist pattern 16 to be formed on the workpiece 10 were 15 μm in thickness and 12 μm in line width. In Example 1, the resist pattern 16 was formed by injecting the atomized developer 14 to the dry film resist in an injection pattern of a hollow cone shape from the nozzle 2 shown in FIG. 2. On the other hand, in Comparative Example 1, the resist pattern 16 was formed by supplying the liquid developer 14 from the shower nozzle to the dry film resist. The resist patterns 16 formed according to Example 1 and Comparative Example 1 were observed using a scanning electron microscope (SEM).

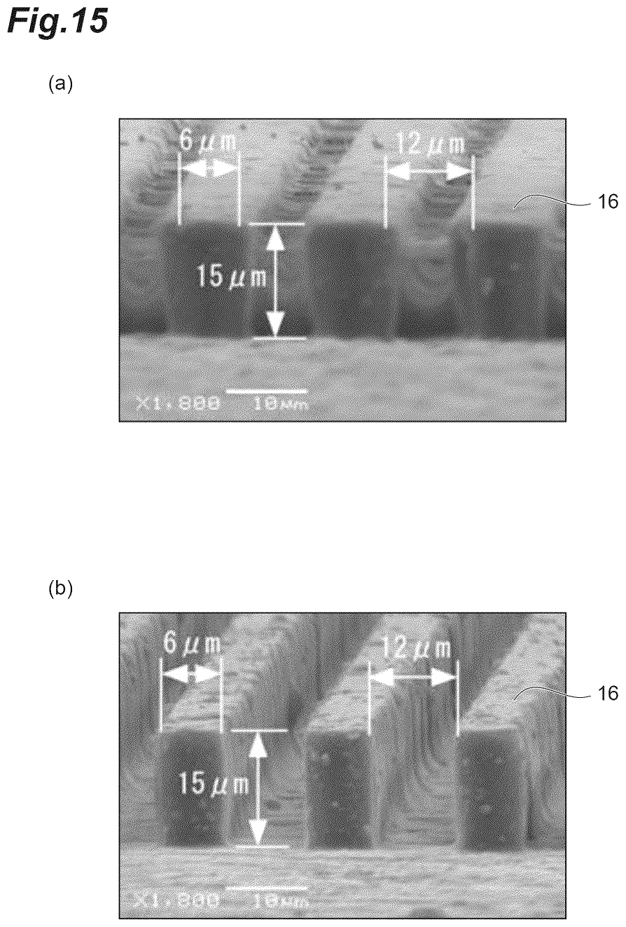

FIG. 15(a) is an SEM photograph of the resist pattern 16 formed according to Comparative Example 1. FIG. 15(b) is an SEM photograph of the resist pattern 16 formed according to Example 1. As shown in FIG. 15(a), it was confirmed that the line width of the resist pattern 16 formed according to Comparative Example 1 was narrower than 12 μm, which is the line width exposed to the dry film resist. In Comparative Example 1, it is considered that the liquid developer 14 penetrated into the dry film resist and the dry film resist swelled, whereby the opening of the resist pattern 16 was reduced. In contrast, as shown in FIG. 15(b), the line width of the resist pattern 16 formed according to Example 1 was 12 μm, and it was confirmed that the resist pattern 16 could be formed with high precision.

Next, Example 2 and Comparative Example 2 will be described. In Example 2 and Comparative Example 2, a photosensitive dry film resist was formed on the workpiece 10, and the dry film resist was exposed and developed by using a photolithography technique to form a resist pattern 16 for sandblasting covering a part of the workpiece 10. The design dimensions of the resist pattern 16 to be formed on the workpiece 10 were 35 μm in thickness and 30 μm in line width. In Example 2, the resist pattern 16 was formed by injecting the atomized developer 14 to the dry film resist in an injection pattern of a hollow cone shape from the nozzle 2 shown in FIG. 2. On the other hand, in Comparative Example 2, the resist pattern 16 was formed by supplying the liquid developer 14 from the shower nozzle to the dry film resist. The resist patterns 16 formed according to Example 2 and Comparative Example 2 were observed using a scanning electron microscope (SEM).

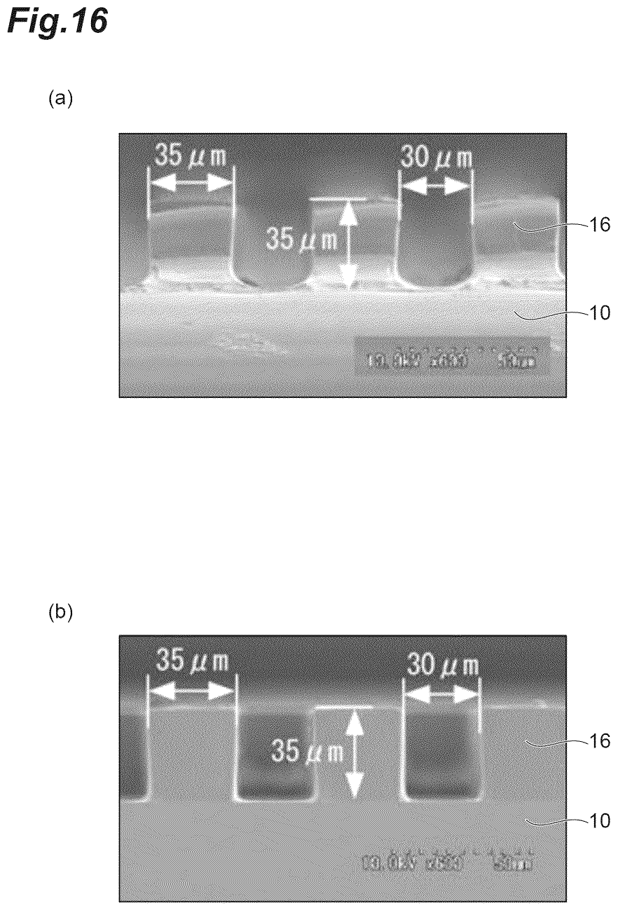

FIG. 16(a) is an SEM photograph of the resist pattern 16 formed according to Comparative Example 2. FIG. 16(b) is an SEM photograph of the resist pattern 16 formed according to Example 2. As shown in FIG. 16(a), in the resist pattern 16 formed according to Comparative Example 2, it was confirmed that the width of the opening was reduced in the vicinity of the bottom portion. It is considered that the reduction of the width of the opening is caused by that a part of the developer supplied from the shower nozzle is retained at the bottom of the opening and the developer 14 is not sufficiently supplied to the side wall of the opening. In contrast, as shown in FIG. 16(b), in the resist pattern 16 formed by Example 2, it was confirmed that the side wall of the opening had high verticality and the resist pattern 16 was developed with high precision.

### REFERENCE SIGNS LIST

1: processing container, 2: nozzle, 3: workpiece conveying mechanism, 4: nozzle conveying mechanism, 5: developer supply device, 6: compressed air supply device (compressed gas supply device), 7: recovery device, 10: workpiece, 12: resist film, 14: developer, 15: compressed air (compressed gas), 16: resist pattern, 20: injection port, 22: housing, 24: liquid supply port, 25: liquid supply pipe, 26: gas supply port, 30: diffusion plate, 32: opening, 36: rod member, 36s: inclined surface, 40: fluid passage, 84: abrasive, 94: stripping liquid, 100: developing device, 221s, 222s, 223s: inner peripheral surface, AX: central axis, θ: angle.

1. A nozzle for injecting a processing liquid, the nozzle comprising a cylindrical housing having a central axis,
wherein the housing comprises:
a liquid supply port to supply the processing liquid into the housing;
a gas supply port to supply a compressed gas into the housing; and
an injection port to inject the processing liquid together with the compressed gas,
wherein the injection port has an annular shape extending around the central axis.

2. The nozzle according to claim 1, further comprising a rod member disposed between the liquid supply port and the injection port in an extending direction of the central axis, the rod member having an inclined surface in which a diameter increases toward the injection port,
wherein a fluid passage is formed between an inner peripheral surface of the housing and the inclined surface to guide the processing liquid supplied from the liquid supply port and the compressed gas supplied from the gas supply port to the injection port.

3. The nozzle according to claim 1, wherein the nozzle is configured to atomize and inject the processing liquid from the injection port.

4. The nozzle according to claim 1, further comprising:
a liquid supply pipe to guide the processing liquid into the housing along the central axis; and
a diffusion plate to diffuse the processing liquid flowing through the liquid supply pipe, the diffusion plate having a plurality of openings arranged along a circumferential direction about the central axis.

5. The nozzle according to claim 1, wherein the processing liquid is a developer to develop a resist film or an etching liquid to etch a workpiece.

6. A developing device for developing a resist film formed on a workpiece, comprising:
a processing container;
a nozzle according to claim 1 disposed in the processing container;
a conveying mechanism to move the workpiece relative to the nozzle in the processing container;
a developer supply device to supply a developer as the processing liquid to the nozzle; and
a compressed gas supply device to supply the compressed gas to the nozzle.

7. The developing device according to claim 6, wherein the developer supply device supplies the developer heated to 40° C. or more to the nozzle.

8. The developing device according to claim 6, further comprising a recovery device to collect a gas containing the developer from the processing container and perform gas-liquid separation.

9. A processing method for a workpiece, comprising:
forming a photosensitive resist film on the workpiece;
exposing the resist film; and
injecting a developer with a compressed gas from a nozzle having an annular injection port to the exposed resist film to form a resist pattern.

10. The processing method according to claim 9, wherein the atomized developer is injected from the injection port.

11. The processing method according to claim 9, wherein the developer is injected in an injection pattern having an annular shape when viewed from a direction along a central axis of the injection port and having a diameter that increases with a distance from the injection port.

12. The processing method according to claim 11, wherein an injecting direction of the developer is inclined at an angle of 10° or less with respect to the central axis.

13. The processing method according to claim 9, further comprising injecting abrasive to the workpiece through the resist pattern to remove a part of the workpiece.

14. The processing method according to claim 9, further comprising injecting an etching liquid from the nozzle to the workpiece through the resist pattern to remove a part of the workpiece.

15. The processing method according to claim 9, further comprising supplying a stripping liquid to the resist pattern to remove the resist pattern from the workpiece.
